(19) United States
(12) Patent Application Publication
(10) Pub. No.: US 2009/0220896 A1
(43) Pub. Date: Sep. 3, 2009

(54) PATTERN FORMING METHOD

(76) Inventors: Katsutoshi Kobayashi, Yokohama-Shi (JP); Kotaro Sho, Yokohama-Shi (JP); Daisuke Kawamura, Matsudo-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/392,905

(22) Filed: Feb. 25, 2009

(30) Foreign Application Priority Data
Feb. 26, 2008 (JP) 2008-044151

(51) Int. Cl. G03F 7/20

(52) U.S. Cl. 430/325

(57) ABSTRACT

A pattern forming method has forming a lower layer film on a film to be processed, forming a silicon-containing intermediate film containing a protecting group which is removed by an acid, on said lower layer film, forming a resist film on said silicon-containing intermediate film, exposing a predetermined region of said resist film to light, and developing said resist film with a developer.

### CROSS REFERENCE TO RELATED APPLICATION

This application is based upon and claims benefit of priority from the Japanese Patent Application No. 2008-44151, filed on Feb. 26, 2008, the entire contents of which are incorporated herein by reference.

### BACKGROUND OF THE INVENTION

The present invention relates to a pattern forming method.

In general, a process for producing a semiconductor device includes many steps of depositing plural materials as a film to be processed on a silicon wafer and patterning them into a desired pattern. In patterning of a film to be processed, firstly, a photosensitive material, which is generally called a resist, is deposited on the film to be processed to form a resist film, and a predetermined region of the resist film is exposed to light.

Subsequently, the exposed portion or unexposed portion of the resist film is removed by development treatment to form a resist pattern, and the film to be processed is subjected to dry etching by use of the resist pattern as an etching mask.

As a light source for exposure, there is used an ultraviolet light such as KrF excimer laser, ArF excimer laser, or the like from the standpoint of throughput. Resolution required in accordance with miniaturization of LSI has been not more than the wavelength of these ultraviolet lights, and light exposure process margin such as light exposure margin, focus margin, or the like has been lacking. In order to enhance resolution, making a resist film thinner has been required, but the conventional single layer resist process cannot secure sufficient dry etching resistance, and highly accurate processing of a film to be processed has been difficult.

As a solution for such a problem, a three-layer-mask process attracts attention, in which a lower layer, an intermediate layer, and an upper resist layer are formed sequentially on a film to be processed, a predetermined pattern is formed in the upper resist layer, and then the intermediate layer, the lower layer, and the film to be processed are etched sequentially (cf. for example, Japanese Patent Laid-Open No. 7-183194).

The intermediate layer has a role of transcribing the pattern in the upper layer to the lower layer by an etching process. The pattern is thereby transcribed to the lower layer through the intermediate layer as a mask, and the lower layer pattern of a high aspect ratio can be obtained.

In this intermediate layer, for example, SiO₂ is used, but in patterning of the upper resist layer, a resist residue is generated between resist patterns. In removing the resist residue, there has been the problem that the upper layer resist patterns are scraped and the desired film thickness cannot be obtained. Furthermore, the generation of a resist residue varies, which causes dimensional fluctuation after etching of the film to be processed. Processing accuracy of the film to be processed is thereby reduced, and there have been the problems that wiring short-circuit occurs and a contact hole is not opened after processing and the like.

### SUMMARY OF THE INVENTION

According to one aspect of the present invention, there is provided a pattern forming method comprising:

forming a lower layer film on a film to be processed;

forming a silicon-containing intermediate film containing a protecting group which is removed by an acid, on said lower layer film;

forming a resist film on said silicon-containing intermediate film;

exposing a predetermined region of said resist film to light; and

developing said resist film with a developer.

According to one aspect of the present invention, there is provided a pattern forming method comprising:

forming a lower layer film on a film to be processed;

coating a silicon-containing intermediate film chemical solution in which an alkali-soluble material having surface orientation is added on said lower layer film;

subjecting said coated silicon-containing intermediate film chemical solution to baking treatment and thereby forming a silicon-containing intermediate film;

forming a resist film on said silicon-containing intermediate film;

exposing a predetermined region of said resist film to light; and

developing said resist film with a developer.

According to one aspect of the present invention, there is provided a pattern forming method comprising:

forming a lower layer film on a film to be processed;

coating a silicon-containing intermediate film chemical solution having titanium oxide added therein on said lower layer film;

subjecting said coated silicon-containing intermediate film chemical solution to baking treatment and thereby forming a silicon-containing intermediate film;

forming a resist film on said silicon-containing intermediate film;

exposing a predetermined region of said resist film to light; and

developing said resist film with a developer.

### BRIEF DESCRIPTION OF THE DRAWINGS

FIG. 1 is a sectional view illustrating a pattern forming method according to an example of the present invention;

FIG. 2 is a sectional view subsequent to FIG. 1;

FIG. 3 is a view showing the structural formula of a tert-butyl ester;

FIG. 4 is a sectional view subsequent to FIG. 2;

FIG. 5 is a sectional view subsequent to FIG. 4;

FIG. 6 is a view showing deprotection of a tert-butyl ester;

FIG. 7 is a sectional view subsequent to FIG. 5;

FIG. 8 is a view showing structural formulas of protecting groups according to modified examples; and

FIG. 9 is a view showing structural formulas of protecting groups according to modified examples.

### DESCRIPTION OF THE EMBODIMENTS

Hereinafter, a pattern formation according to an example of the present invention will be explained on the basis of the drawings.

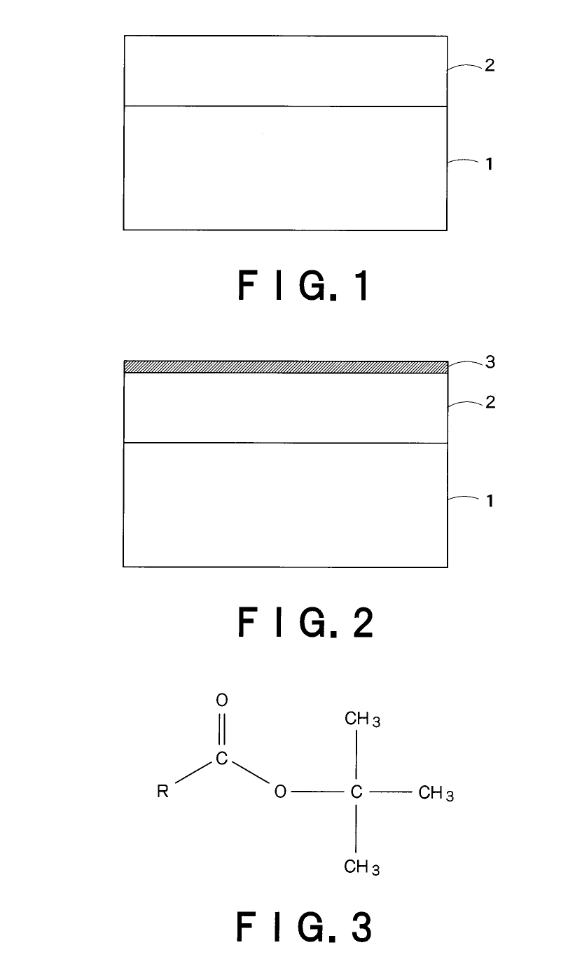

In FIG. 1 to FIG. 7 (excluding FIG. 3 and FIG. 6), there are shown stepwise sectional views in the pattern forming process according to an example of the present invention. As shown in FIG. 1, an organic lower layer film 2 is formed on a silicon substrate 1 by spin coating method so as to have a film thickness of 3000 Å, and is subjected to baking treatment. The organic lower layer film 2 is, for example, a novolac resin.

As shown in FIG. 2, a silicon-containing intermediate film 3, which contains silicon and has photoreactivity, is formed on the organic lower layer film 2 by a spin coating method so as to have a film thickness of 450 Å, and is subjected to baking treatment. As the intermediate film 3 having photoreactivity, there is used, for example, a film that has a protecting group to be removed by an acid and becomes alkali-soluble following the deprotection. For example, a tert-butyl ester wherein a carboxyl group is protected by use of tert-butyl group (tertiary butyl group) as a protecting group can be used.

The silicon-containing intermediate film 3 can be formed by coating a silicon-containing intermediate film chemical solution (for example, siloxane solution) having a tert-butyl ester added therein, for example, so as to give a concentration of 5 wt. % by a spin coating method and subjecting the solution to baking treatment. The structural formula of a tert-butyl ester is shown in FIG. 3.

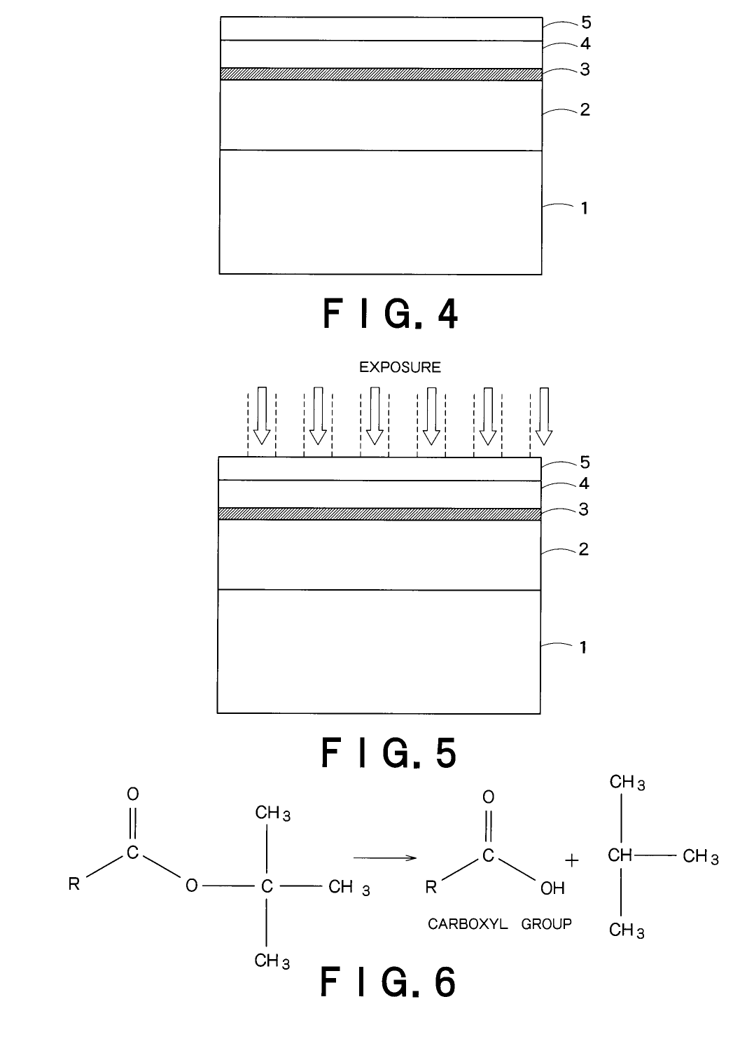

As shown in FIG. 4, a positive DUV (Deep Ultra Violet) resist film 4 for ArF (argon fluoride) is formed on the silicon-containing intermediate film 3 by a spin coating method so as to have a film thickness of 1000 Å, and is subjected to baking treatment. Furthermore, a protective film 5 for immersion photolithography is formed on the resist film 4 by spin coating method so as to have a film thickness of 900 Å, and is subjected to baking treatment.

As shown in FIG. 5, pattern exposure is carried out with ArF excimer laser aligner (not shown in the drawing) by use of a half-tone mask having, for example, a transmittance of 6% under the conditions of NA=1.20, σ=0.938/0.834, and Quaser illumination. Light exposure is, for example, 20 mJ/cm².

By this exposure treatment, the protecting group in the silicon-containing intermediate film 3 is removed protection. For example, as shown in FIG. 6, tert-butyl ester is deprotected and returned to a carboxyl group.

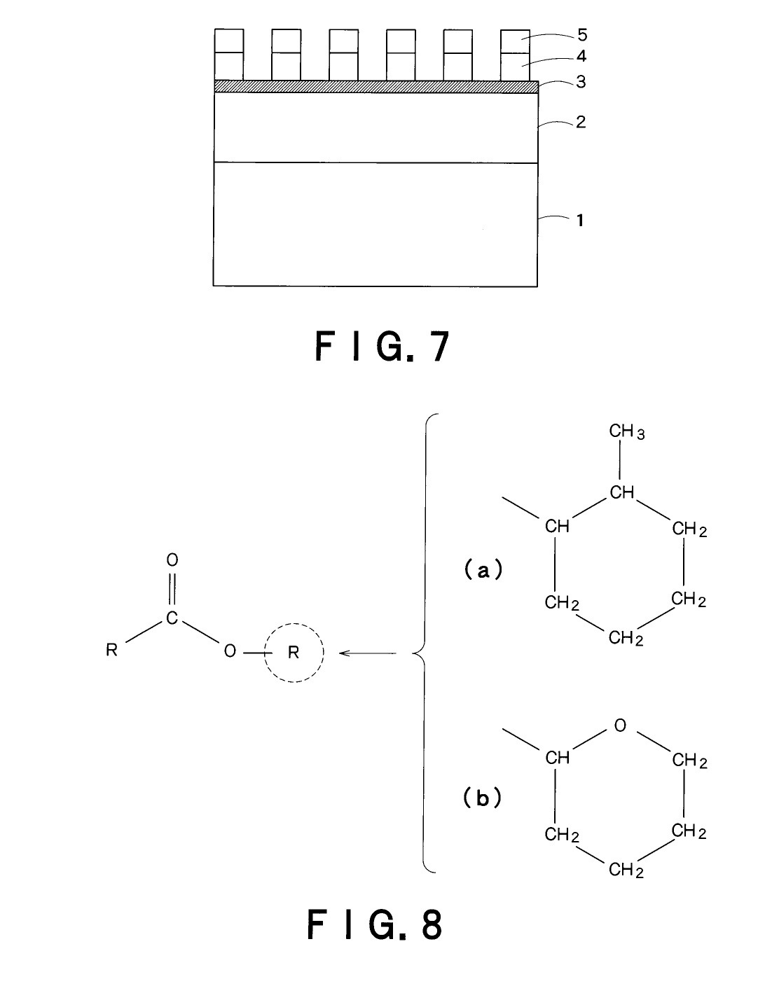

As shown in FIG. 7, an L/S pattern of 43 nm is formed by carrying out baking treatment and paddle development for 30 seconds using 2.38 wt. % tetramethylammonium hydroxide (TMAH) aqueous solution. The carboxyl group contained in the silicon-containing intermediate film 3 is alkali-soluble and hence is dissolved by development treatment.

The resist residue thickness in the recess between patterns of the resist patterns after the development treatment was 4 Å. The resist residue between resist patterns can be reduced by incorporating a material, which is deprotected by an acid and becomes alkali-soluble, in the silicon-containing intermediate film 3.

In addition, unexposed portions of the silicon-containing intermediate film 3 have adhesion with the resist film 4 and remain alkali-insoluble.

### Comparative Example

The pattern forming process according to a comparative example will be explained. In the pattern forming process according to the comparative example, an intermediate film having no photoreactivity was used and the other procedures in the pattern forming were carried out similarly to the above example.

In this case, the resist residue thickness in the recess between patterns of the resist patterns after the development treatment was measured as 26 Å.

On the other hand, in the pattern forming process according to the above example, the resist residue after the exposure and development treatments can be reduced by incorporating a material, which is deprotected by an acid and becomes alkali-soluble, in the intermediate film in the three-layer-mask process.

Thus, the pattern forming process according to the present example can reduce a resist residue and enhance accuracy of the processing.

In the above example, a carboxyl group was protected by use of a tert-butyl group as a protecting group, but it may be protected by use of (a) a methylcyclohexyl group or (b) a tetrahydropyranyl group as shown in FIG. 8.

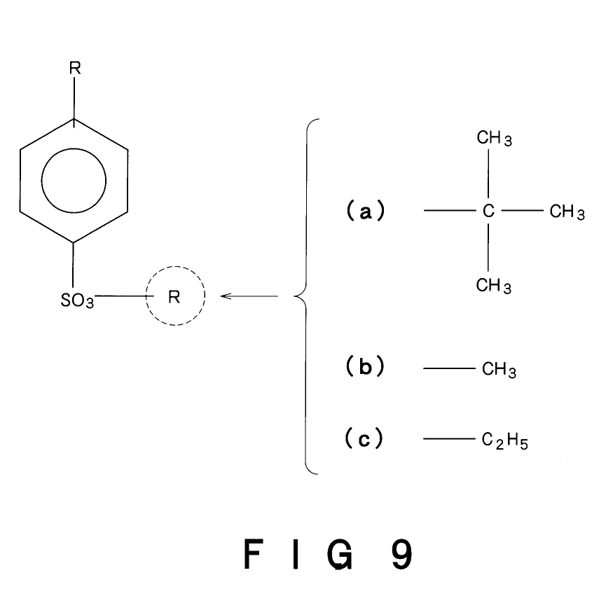

Furthermore, in place of the protected carboxyl group, a benzenesulfonic acid group protected by use of (a) a tert-butyl group, (b) a methyl group, or (c) an ethyl group as shown in FIG. 9 may be added in SOG liquid and spin-coated to form the silicon-containing intermediate film 3.

Moreover, an alkali-soluble and surface orientational material such as a dehydration condensation polymer such as polyacrylic acid, polyallylamine, or a silicon-containing resist may be added in the silicon-containing intermediate film chemical solution. The alkali-soluble material is formed at the surface portion of the intermediate film 3 and dissolved in a developer during the development treatment, and a resist residue can be reduced.

Furthermore, TiO₂ (titanium oxide) may be added in the silicon-containing intermediate film chemical solution. The titanium oxide has the effect as a photocatalyst decomposing an organic substance. Therefore, adding the titanium oxide makes decomposition of resist residue possible and can reduce resist residue.

Moreover, instead of adding a material in the silicon-containing intermediate film chemical solution, after formation of the silicon-containing intermediate film, an alkali-soluble film such as, for example, a silicon-containing resist film may be formed by spin-coating to form a final intermediate film. The thickness of the alkali-soluble film is preferably not more than 10 nm.

What is claimed is:

1. A pattern forming method comprising:
forming a lower layer film on a film to be processed;
forming a silicon-containing intermediate film containing a protecting group which is removed by an acid, on said lower layer film;
forming a resist film on said silicon-containing intermediate film;
exposing a predetermined region of said resist film to light; and
developing said resist film with a developer.

2. The pattern forming method according to claim 1, wherein said silicon-containing intermediate film becomes alkali-soluble by removal of said protecting group.

3. The pattern forming method according to claim 1, wherein said silicon-containing intermediate film is formed by
coating a silicon-containing intermediate film chemical solution in which the protecting group removed by an acid is added on said lower layer film, and
subjecting said coated silicon-containing intermediate film chemical solution to baking treatment.

4. The pattern forming method according to claim 1, wherein said protecting group comprises a tert-butyl ester.

5. The pattern forming method according to claim 1, wherein said protecting group is formed by protecting a carboxyl group with a methylcyclohexyl group.

6. The pattern forming method according to claim 1, wherein said protecting group is formed by protecting a carboxyl group with a tetrahydropyranyl group.

7. The pattern forming method according to claim 1, wherein said protecting group is formed by protecting a benzenesulfonic acid group with a tert-butyl group.

8. The pattern forming method according to claim 1, wherein said protecting group is formed by protecting a benzenesulfonic acid group with a methyl group.

9. The pattern forming method according to claim 1, wherein said protecting group is formed by protecting a benzenesulfonic acid group with an ethyl group.

10. A pattern forming method comprising:
forming a lower layer film on a film to be processed;
coating a silicon-containing intermediate film chemical solution in which an alkali-soluble material having surface orientation is added on said lower layer film;
subjecting said coated silicon-containing intermediate film chemical solution to baking treatment and thereby forming a silicon-containing intermediate film;
forming a resist film on said silicon-containing intermediate film;
exposing a predetermined region of said resist film to light; and
developing said resist film with a developer.

11. The pattern forming method according to claim 10, wherein said alkali-soluble material comprises a dehydration condensation polymer.

12. The pattern forming method according to claim 11, wherein said dehydration condensation polymer is formed by polyacrylic acid or polyallylamine.

13. The pattern forming method according to claim 10, wherein said alkali-soluble material is a silicon-containing resist.

14. A pattern forming method comprising:
forming a lower layer film on a film to be processed;
coating a silicon-containing intermediate film chemical solution having titanium oxide added therein on said lower layer film;
subjecting said coated silicon-containing intermediate film chemical solution to baking treatment and thereby forming a silicon-containing intermediate film;
forming a resist film on said silicon-containing intermediate film;
exposing a predetermined region of said resist film to light; and
developing said resist film with a developer.
